(19) United States
(12) Patent Application Publication
(10) Pub. No.: US 2025/0338673 A1
(43) Pub. Date: Oct. 30, 2025

(54) Mass-transferable microLEDs with high wafer utilization

(71) Applicant: Lumileds LLC, San Jose, CA (US)

(72) Inventors: Zhongmin REN, Danville, CA (US); Rajiv PATHAK, Milpitas, CA (US); Brendan Jude Moran, San Jose, CA (US); ShiMin LIM, Singapore (SG); Boon Hon Tan, Singapore (SG)

(73) Assignee: Lumileds LLC, San Jose, CA (US)

(21) Appl. No.: 18/647,275

(22) Filed: Apr. 26, 2024

(51) Int. Cl. H01L 33/00; H01L 21/67

(52) U.S. Cl. CPC H10H 20/018; H01L 21/67144

(57) ABSTRACT

A light-emitting apparatus includes a carrier substrate, an array of light-emitting devices on the carrier substrate, and carrier posts connecting the light-emitting devices to the carrier substrate spaced apart from the carrier substrate. The carrier post forms the only attachment between each light-emitting device and the carrier substrate, is positioned within the areal extent of the light-emitting device, and is attached to the light-emitting device at an attachment area thereof that occupies only a fractional portion of the areal extent of the light-emitting device. A transfer substrate can adhere to the light-emitting devices and then be separated from the carrier substrate with the light-emitting devices adhered thereto. The light-emitting devices can then be attached to a backplane, interconnect layer, or circuit board and the transfer layer removed leaving the behind the attached light emitting devices.

### FIELD OF THE INVENTION

The field of the present invention relates to mass-transfer of microLEDs.

### SUMMARY

An inventive light-emitting apparatus includes a carrier substrate, a multitude of semiconductor light-emitting devices, and for each light-emitting device, a corresponding carrier post. The light-emitting devices are arranged as an array on the carrier substrate, and the array of light-emitting devices is characterized by an array spacing, a device size, and a device separation. The array can include 10⁴ or more light-emitting devices, the array spacing can be less than 200 microns (or even less), or the device separation can be less than 50 microns (or even less). Each carrier post connects the corresponding light-emitting device to the carrier substrate; thus connected, the light-emitting device is spaced apart from the carrier substrate. The carrier post forms the only attachment between the light-emitting device and the carrier substrate, is positioned within the areal extent of the light-emitting device, and is attached to the light-emitting device at an attachment area thereof that occupies only a fractional portion of the areal extent of the light-emitting device. Tensile strength of an interface between each carrier post and the attachment area of the corresponding light-emitting device can be less than that of the light-emitting device, the carrier post, or the interface between the carrier post and the carrier substrate.

An inventive method begins with depositing one or more polymer precursors onto a multitude of semiconductor light-emitting devices, which are arranged as an array on a support substrate. The polymer precursor covers, and fills spaces between, the light-emitting devices of the array. After their deposition, the polymer precursor(s) are cured to form a solid polymer layer. On an attachment area of each one of the light-emitting devices is formed a corresponding carrier post with a first end of each carrier post attached to the attachment area of the corresponding light-emitting device. The carrier posts can be formed before depositing the polymer precursor(s), or after curing to form the polymer layer (e.g., by etching through the polymer layer and forming the carrier post in the resulting hole, in some examples further including a layer of carrier post material on the polymer layer between the carrier posts). The carrier posts extend through the polymer layer so that a second end of each of the carrier posts is exposed at a surface of the polymer layer. Each of the carrier posts is positioned within an areal extent of the corresponding light-emitting device, and the attachment area of each light-emitting device occupies only a fractional portion of the areal extent thereof. Next, a carrier substrate is formed on or attached to the surface of the polymer layer, with the carrier substrate attached to the exposed second ends of the carrier posts, and with the light-emitting devices between the support substrate and the carrier substrate. The support substrate is then removed from the light-emitting devices, after which the polymer layer is removed from the light-emitting devices and the carrier substrate. The carrier posts are left as the only attachment between each light-emitting device and the carrier substrate, with the light-emitting devices spaced apart from the carrier substrate.

An inventive method can further include adhering a transfer substrate to the array of light-emitting devices with the light-emitting devices between the carrier substrate and the transfer substrate, and then separating the transfer substrate from the carrier substrate so that the carrier posts separate from the corresponding light emitting-devices and the array of light-emitting devices remains adhered to the transfer substrate. Tensile strength of the interface between the attachment area of each light-emitting device and the corresponding carrier post can be less than that of the light-emitting devices, the carrier posts, attachment of the carrier posts to the carrier substrate, and the interface between the transfer substrate and the light-emitting devices.

An inventive method can still further include attaching the array of light-emitting devices to a backplane, interconnect layer, or circuit board with the light-emitting devices between the transfer substrate and the backplane, interconnect layer, or circuit board, and then separating the transfer substrate from the array of light-emitting devices so that the light-emitting devices remain attached to the backplane, interconnect layer, or circuit board.

Objects and advantages pertaining to mass-transfer of microLEDs may become apparent upon referring to the example embodiments illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a top schematic view of an example of an array of polychromic LEDs and an enlarged section of 3×3 polychromic LEDs of the array.

FIGS. 2A and 2B are schematic plan and side views of a set of semiconductor LEDs attached to a carrier substrate with carrier posts.

FIGS. 3A-3H illustrate schematically a first example method for attaching a set of semiconductor LEDs to a carrier substrate with carrier posts; FIGS. 4A-4H illustrate schematically a second example method for attaching a set of semiconductor LEDs to a carrier substrate with carrier posts; FIGS. 5A-5G illustrate schematically a third example method for attaching a set of semiconductor LEDs to a carrier substrate with carrier posts.

FIGS. 6A-6D illustrate schematically an example method for transferring a set of semiconductor LEDs from a carrier substate to another substrate or element.

FIGS. 7A and 7B are schematic side and bottom views of a first example arrangement of a semiconductor LED attached to a carrier substate with a carrier post.

FIGS. 8A and 8B are schematic side and bottom views of a second example arrangement of a semiconductor LED attached to a carrier substate with a carrier post.

FIG. 9 is a set of micrographs of showing transfer of a set of semiconductor LEDs arranged as in FIGS. 7A and 7B from a carrier substrate to a transfer substrate.

FIG. 10 is a set of micrographs of showing transfer of a set of semiconductor LEDs arranged as in FIGS. 8A and 8B from a carrier substrate to a transfer substrate.

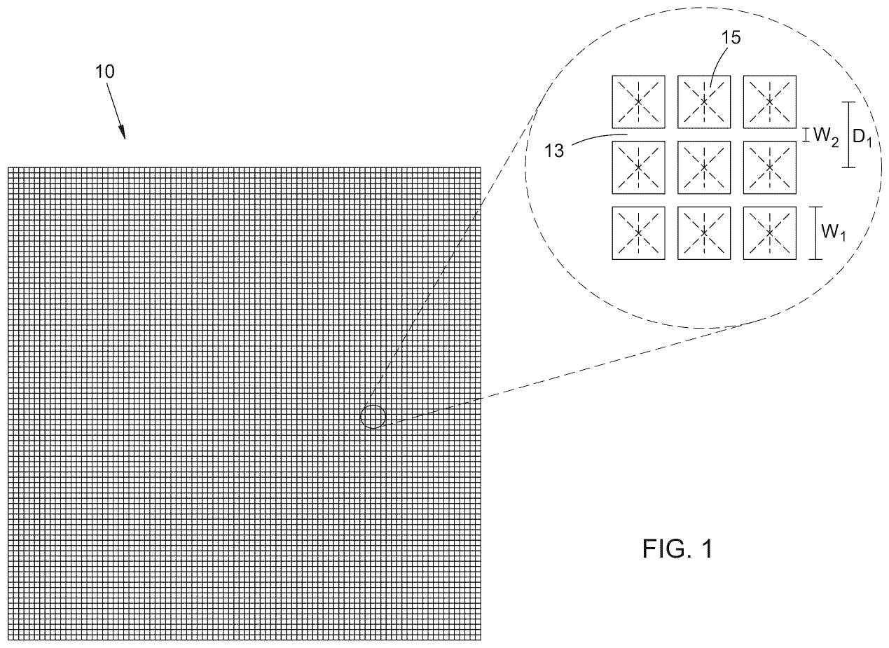

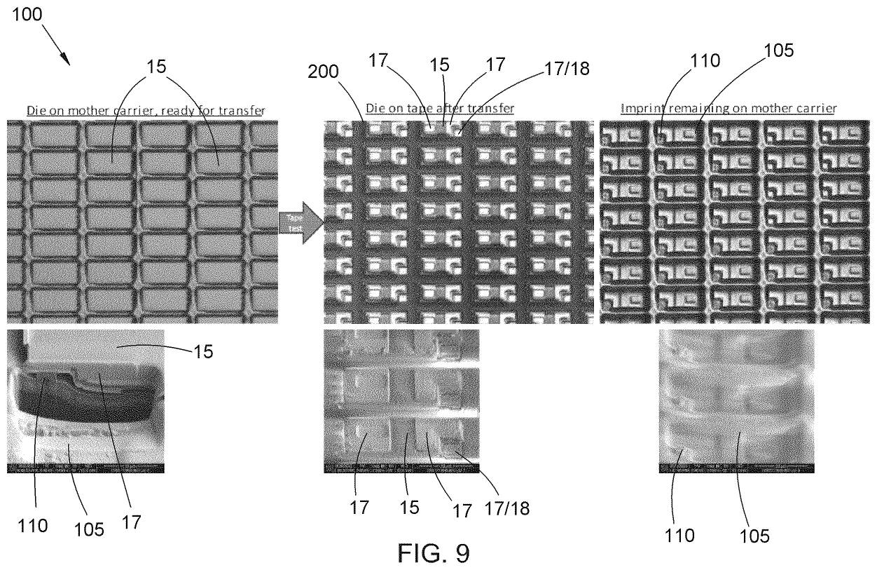

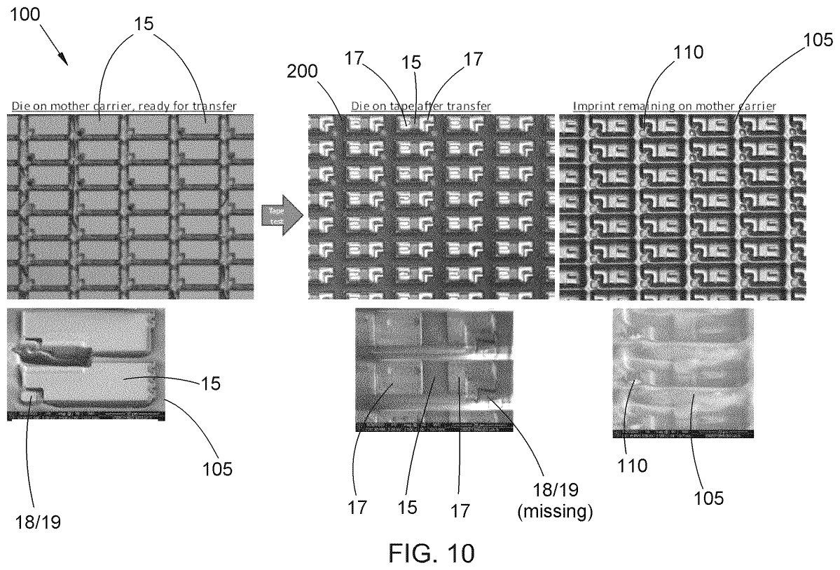

The embodiments depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. In the drawings (e.g., in FIGS. 1 through 8B), some schematic illustrations of example structures of various devices and assemblies described herein may be shown with precise right angles and straight lines, but it is to be understood that such schematic illustrations may not reflect real-life process limitations or defects. Such process limitations or defects can cause the features to look not so “ideal” when any of the structures described herein are examined using, e.g., scanning electron microscopy (SEM) images or transmission electron microscope (TEM) images. In such images of real structures (e.g., as in FIGS. 9 and 10), possible processing limitations or defects might be visible, e.g., not-perfectly straight edges of materials, tapered vias or other openings, inadvertent rounding of corners or variations in thicknesses of different material layers. There may be other limitations or defects not listed here that can occur within the field of device fabrication. The embodiments shown are only examples and should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter.

MicroLEDs (i.e., semiconductor light-emitting diodes having individual device sizes less than, e.g., 200 microns or 100 microns) exhibit favorable performance, efficiency, reliability, and color gamut compared to liquid-crystal displays (LCD), organic LED displays (OLEDs), or miniLED displays (LEDs having individual device sizes from about a millimeter down to a few hundred microns). There are challenges faced when employing microLEDs for a direct-view display. Wafer utilization (e.g., die-per-wafer, or DPW) can in some instances be relatively low, driving up the cost of the final display and the feasibility of the using microLEDs in various display applications. Also, mass transfer speed and yield can be significantly affected by device design and process development.

Accordingly, it would be desirable to provide an inventive arrangement of microLEDs in which (1) relatively high wafer utilization can be achieved with high DPW and (2) the microLEDs are mass transferable in large numbers (e.g., 10⁴ or more microLEDs in an array) with high yield and speed. In addition, such an inventive arrangement of microLEDs can be: (3) compatible with various mass transfer technologies, including transfer tape or film, stamp transfer, vacuum head transfer, electrostatic transfer, or laser transfer; (4) compatible with various microLED designs, including flip-chip die, vertical die, single or multiple contact pads, single-color die, or polychromic die; or (5) applicable to various types of LED wafers, e.g., InGaN microLEDs on a sapphire substrate, InGaN microLEDs on a silicon substrate, AlInGaP microLEDs on a GaAs substrate, or AlGaAs microLEDs on a GaAs substrate.

Arrays of microLEDs can include any suitable number of individual light-emitting devices, e.g., on the order of 10¹, 10², 10³, 10⁴, 10⁵, 10⁶, or more microLEDs. An example of an array 10 of microLEDs 15 is illustrated schematically in FIG. 1. The individual microLEDs 15 (also referred to as pixels, particularly when the array 10 is employed as a display) can be characterized by a device size or width w₁ (e.g., side lengths) in the plane of the array 10, for example, less than 200 microns, less than 100 microns, less than 50 microns, less than 20 microns, less than 10 microns, less than 5 microns, less than 2 microns, or as small as 1 micron. MicroLEDs 15 in the array 10 can be spaced apart from each other by streets, lanes, or trenches 13 so that the array 10 can be characterized by a device separation w₂ in the plane of the array 10 of, for example, less than 50 microns, less than 20 microns, less than 10 microns, less than 5 microns, less than 2 microns, or less than 1 micron. The pixel pitch or array spacing D₁ is the sum of w₁ and w₂; the pixel separation or device separation is equal to w₂. Although the illustrated examples show rectangular microLED pixels 15 arranged in a rectangular array 10, the pixels and the array can have any suitable shape or arrangement, whether symmetric or asymmetric. Multiple separate arrays of microLEDs 15 can be combined in any suitable arrangement in any applicable format to form a larger combined array or display.

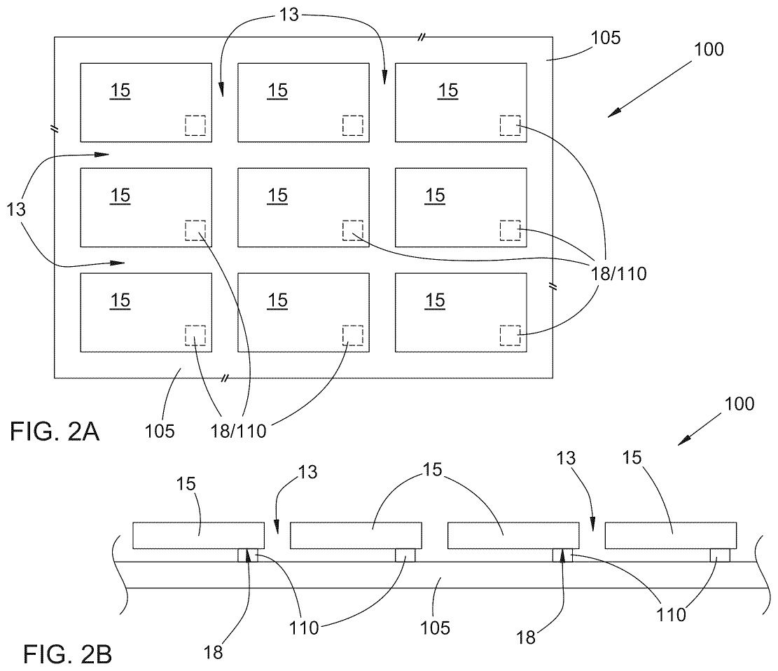

Examples of inventive light-emitting apparatus 100 are illustrated schematically in FIGS. 2A and 2B. A multitude of semiconductor light-emitting devices 15 are arranged as an array 10 on a carrier substrate 105. In some examples the light-emitting devices 15 comprise light-emitting diodes (LEDs) that include one or more doped or undoped III-V semiconductor materials or combinations, mixtures, or alloys thereof, and can be arranged in any suitable LED architecture, such as flip-chip die, vertical die, single or multiple contact pads, single-color die, or polychromic die. In the drawings the light-emitting devices 15 are depicted schematically as featureless rectangles, omitting details of their layer structures, arrangements, LED architecture (including those described herein). As noted above, the light-emitting devices 15 can be arranged as microLEDs with the device separation (w₂) being less than 50 microns, less than 20 microns, less than 10 microns, less than 5 micron, less than 2 micron, or less than 1 micron, and with the device spacing (D₁) being less than 200 microns, less than 100 microns, less than 50 microns, less than 20 microns, less than 10 microns, less than 5 microns, less than 2 microns, or less than 1 micron. In some examples the array 10 can include a large number of individual devices 15, e.g., an array of 10², 10³, 10⁴, 10⁵, 10⁶, or more light-emitting devices 15. The light-emitting devices 15 can be arranged in any suitable

A carrier post 110 connects each light-emitting device 15 of the array to the carrier substrate 105 so that the light-emitting device 15 is spaced apart from the carrier substrate 105. Each carrier post 110 forms the only attachment between the corresponding light-emitting device 15 and the carrier substrate 105. As illustrated schematically in FIGS. 2A and 2B, each carrier post 110 is positioned beneath the corresponding light-emitting device 15, within the areal extent (i.e., within the outline or “footprint”) of that light-emitting device (indicated by the dashed lines). Each carrier post 110 is attached to the corresponding light-emitting device 15 at an attachment area 18 thereof that occupies only a fractional portion of the areal extent of the light-emitting device 15. The carrier posts can be made of any suitable one or more materials, e.g., one or more metallic, dielectric, or polymeric materials, so that the carrier posts 110 are sufficiently rigid and strong to hold the light-emitting devices 15 in place attached to the carrier substrate 105. In some examples the carrier posts 110 can include silicon oxide, silicon nitride, silicon oxynitride, or other metal or semiconductor oxides, nitrides, or oxynitrides. The attachment area 18 of each of the light-emitting devices 15 can include one or more metallic or dielectric materials, e.g., aluminum, copper, nickel, silver, or gold; titanium tungsten alloy, titanium tungsten nitride, transparent conductive oxide (i.e., TCO; e.g., indium tin oxide or indium zinc oxide); or silicon oxide, nitride, or oxynitride, or other metal or semiconductor oxide, nitride, or oxynitride.

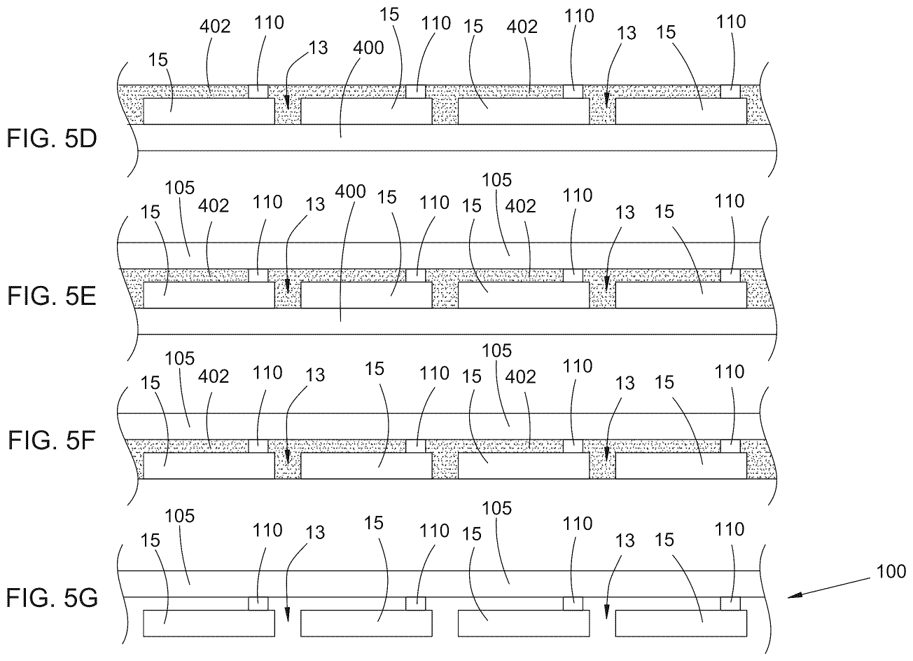

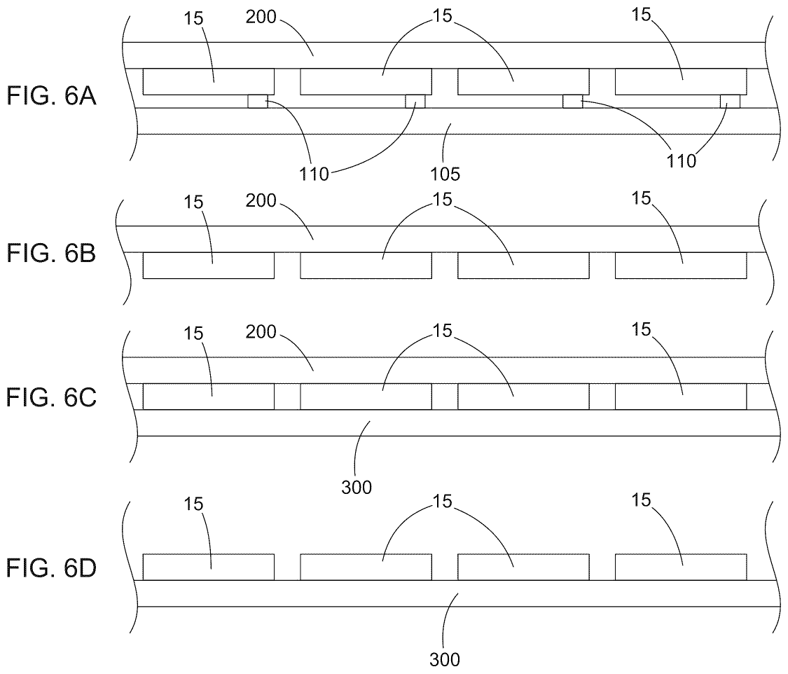

The carrier posts 110 are arranged to attach the light-emitting devices 110 to the carrier substrate 105 in a suitable array arrangement (e.g., as in FIGS. 2A and 2B) for simultaneous mass transfer of many light-emitting devices 15 to another substrate 200 (e.g., a transfer tape, transfer film, or other transfer substrate 200) or to a transfer tool (e.g., a stamp transfer tool, a vacuum head transfer tool, an electrostatic transfer tool, or a laser transfer tool). An example method is illustrated schematically in FIG. 6A through 6D. Once positioned on and adhered to or held by the transfer substrate 200 or transfer tool (e.g., as in FIG. 6A), the light-emitting devices 15 can be separated from the corresponding carrier posts 110 (and the carrier substrate 105) at an interface between each carrier post 110 and the attachment area 18 of the corresponding light-emitting device 15 (e.g., as in FIG. 6B). Depending on the materials of the carrier posts 110 and the attachment areas 18, the interface between the attachment areas 18 and the carrier posts 110 can be a metal-metal interface, a metal-dielectric interface, a dielectric-dielectric interface, a metal-polymer interface, or a dielectric-polymer interface. To facilitate the separation at the correct location, the interface between the attachment areas 18 and the carrier posts 110 can be arranged to exhibit tensile strength that is less than tensile strength of the carrier post 110, less than tensile strength of an attachment of the carrier post 110 to the carrier substrate 105, and less than tensile strength of the light-emitting devices 15.

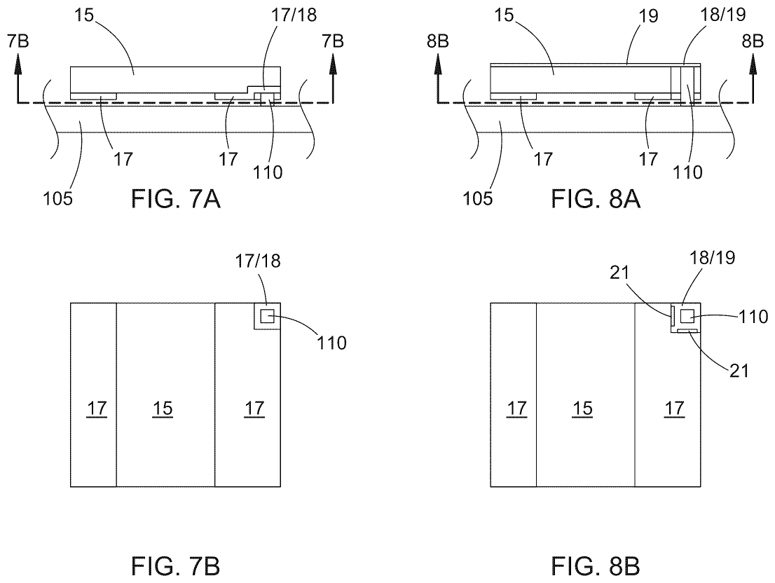

In some examples (e.g., as in FIGS. 7A and 7B), the attachment area 18 of each light-emitting device 15 can include one or more metallic materials in electrical contact with, or forming at least a portion of, an electrical contact 17 of the light-emitting device. Upon separation of the carrier post 110 from the attachment area 18, the electrical contact 17 is left exposed for an electrical connection to be formed later. In some other examples (e.g., as in FIGS. 8A and 8B), the attachment area 18 can include a portion of a dielectric layer 19 that extends across at least a portion of the light-emitting device 15. The dielectric layer 19 can include one or more grooves or perforations 21 that form an interface between the attachment area 18 and a remainder of the dielectric layer 19. The groove(s) or perforation(s) 21 result in tensile strength of the interface being less than tensile strength exhibited by the carrier post 110, less than tensile strength exhibited by an attachment of the carrier post 110 to the carrier substrate 105, and less than tensile strength exhibited by the light-emitting device 15.

The inventive arrangement the light-emitting apparatus 100 enables many light-emitting devices 15 to be transferred simultaneously from the carrier substrate 105 to another structure or element 300 (e.g., a backplane, interconnect layer, or circuit board) using the transfer substrate 200 or the transfer tool. After separation from the carrier substrate 110, the light-emitting devices 15 on the transfer substrate 200 or transfer tool can be positioned on the structure or element 300 and then attached thereto (e.g., as in FIG. 6C). After that attachment, the transfer substrate 200 or transfer tool can be separated from the light-emitting devices 15, leaving them attached to the structure or element 300 (e.g., a backplane, interconnect layer, circuit board, or other structure; as in FIG. 6D).

For a given size of the light-emitting devices 15, the inventive arrangement of the apparatus 100 can enable relatively higher wafer utilization, or relatively higher DPW, than previous arrangements of microLEDs on a carrier substrate for mass transfer. In particular, the placement of the carrier posts 110 between the light-emitting device 15 and the carrier substrate 110, with each carrier post 110 positioned within the areal extent of the corresponding light-emitting device 15 (i.e., the device “footprint”), reduces the minimum device spacing that can be achieved in the array on the carrier substrate. Previous carrier substrate arrangements include a connection between the light-emitting devices and the carrier substrate using laterally extending connecting members. The placement of the connecting members at the periphery of the light-emitting devices in those previous arrangements necessitates that the device separation be increased to accommodate the lateral connecting members, which in turn drives down wafer utilization and DPW.

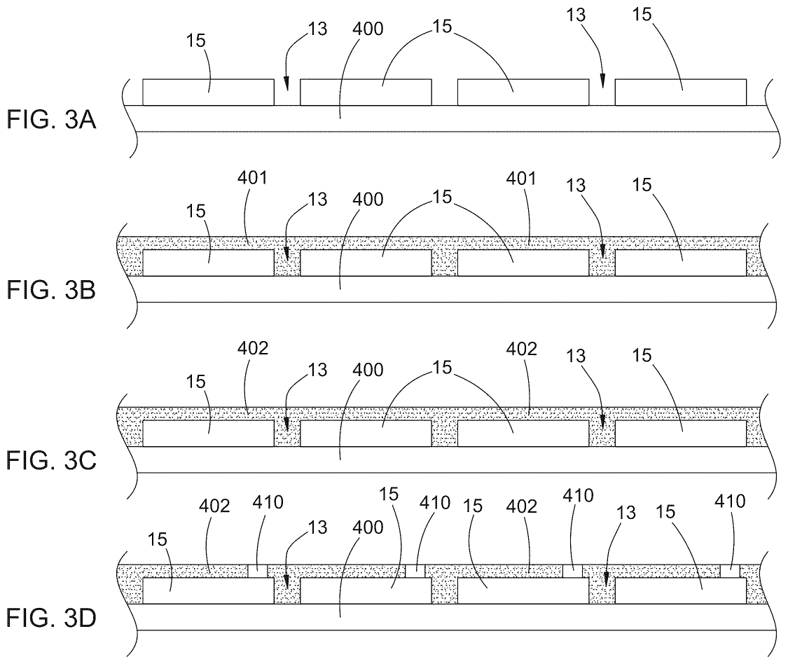

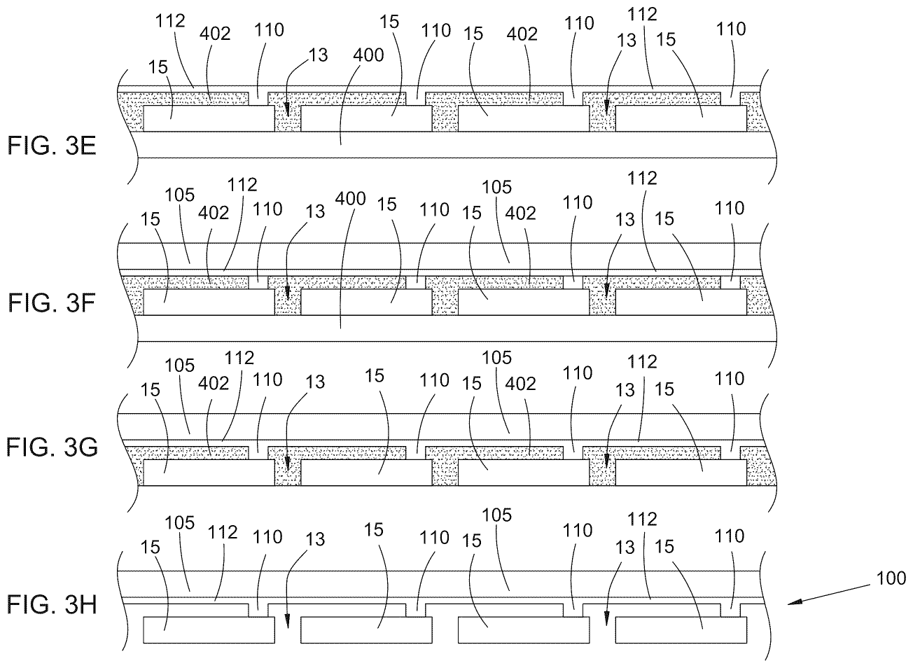

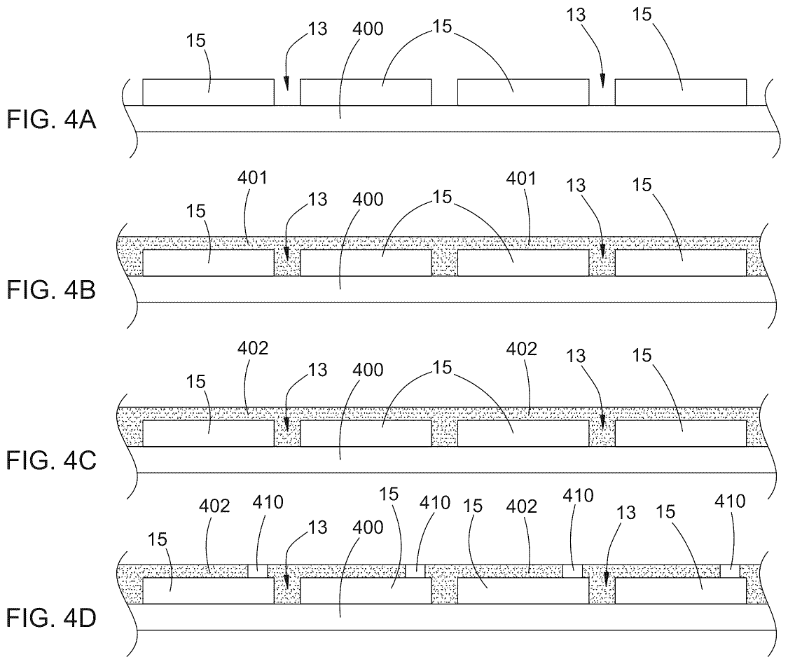

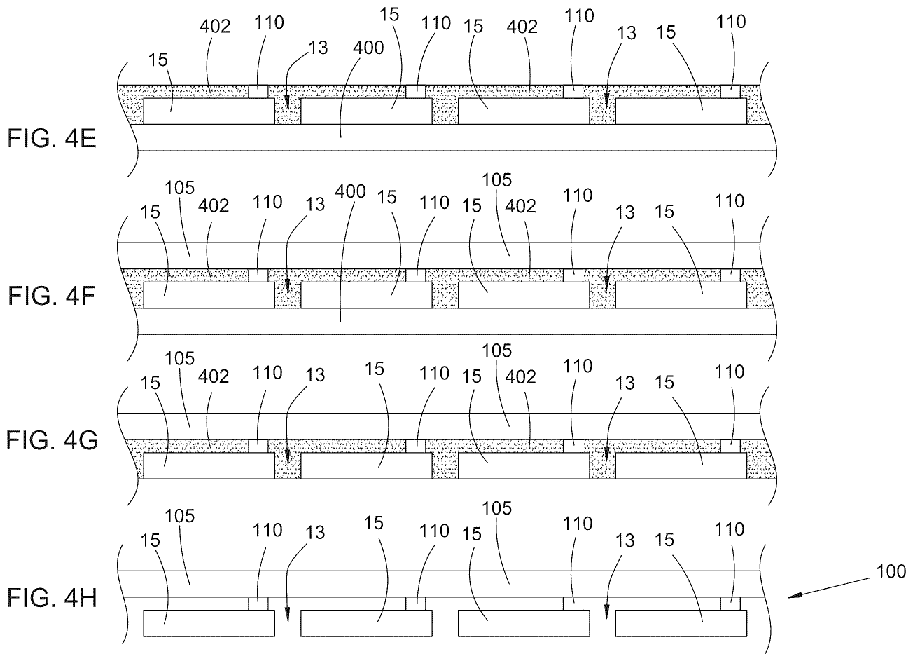

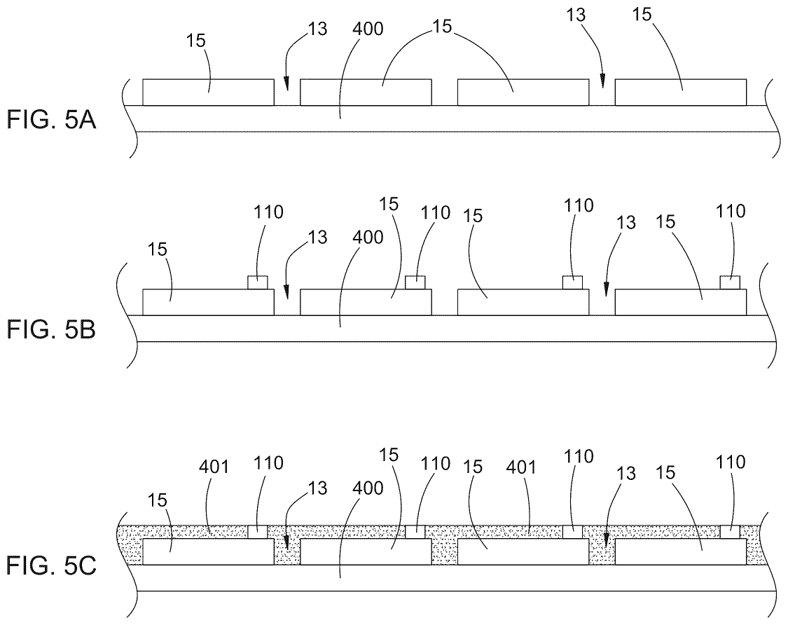

Example fabrication sequences are illustrated schematically in FIGS. 3A-3H, 4A-4H, and 5A-5G. One or more polymer precursors 401 are deposited onto a multitude of semiconductor light-emitting devices 15 arranged as an array on a support substrate 400 (shown in FIGS. 3A, 4A, and 5A before deposition of the polymer precursors 401). The support substate 400 can in some examples be a substrate on which the light-emitting device 15 were fabricated, e.g., InGaN microLEDs 15 on a sapphire substrate 400, InGaN microLEDs 15 on a silicon substrate 400, AlInGaP microLEDs 15 on a GaAs substrate 400, or AlGaAs microLEDs 15 on a GaAs substrate 400. In other examples the light-emitting devices 15 can be assembled onto the support substrate 400. The one or more deposited polymer precursors 401 typically are liquid or semiliquid; examples of suitable precursors 401 can include, e.g., one or more acrylate monomers, cyclopentanone, propylene glycol monomethyl ether, polyaliphatic imide copolymer, and so forth. The deposited polymer precursors 401 cover, and fill spaces 13 between, the light-emitting devices 15 of the array (e.g., as in FIGS. 3B, 4B, and 5C). The polymer precursors 401 are then cured (e.g., by heat or UV irradiation) to form a solid polymer layer 402 (e.g., as in FIGS. 3C, 4C, and 5D). The carrier posts 110 are formed on the attachment areas of the light-emitting devices 15 (within the areal extend of the light-emitting devices 15, as discussed above), with each carrier post 110 attached at its first end to the attachment area 18 of the corresponding light-emitting device 15. The carrier posts 110 extend through the polymer layer 402 so that their second ends are exposed at the surface of the polymer layer 402 (e.g., as in FIGS. 3E, 4E, and 5D).

In some examples (e.g., as in FIGS. 5A-5D) the carrier posts 110 can be formed before depositing the polymer precursors 401. The deposited polymer precursors 401 fill spaces surrounding the carrier posts 110, so that the carrier posts 110 are embedded in and extend through the solid polymer layer 402 after curing. In some other examples (e.g., as in FIGS. 3A-3E and 4A-4E) each carrier post 110 can be formed after forming the polymer layer 402, e.g., by etching a corresponding hole 410 through the solid polymer layer 402 to expose the attachment area 18 of each light-emitting device 15 of the array, and then forming the corresponding carrier post 110 in each of the holes. In some examples (e.g., as in FIG. 3E), additional carrier post material can be deposited to form a layer 112 on the polymer layer 402 that extends between the carrier posts 110. Any suitable deposition process can be employed to form the layer 112 (if present) on the polymer layer 402 and the carrier posts 110 in the holes 410, e.g., chemical vapor deposition (CVD) or any suitable type, sputtering, thermal evaporation, e-beam evaporation, or spin coating. In some examples that surface of the polymer layer 402 and the exposed second ends of the carrier posts 110 can be planarized by any suitable method, e.g., chemical mechanical polishing (CMP); such planarization can be employed in some instances, e.g., to form the structures shown in FIGS. 4E or 5D.

The carrier substrate 105 is formed on, or attached to, the surface of the polymer layer 402 (e.g., as in FIGS. 4F or 5E) or to the layer 112 of carrier post material (e.g., as in FIG. 3F), so that the carrier substrate 105 is attached to the exposed ends of the carrier posts 110, and so that the light-emitting devices 15 are between the support substrate 400 and the carrier substrate 105. The carrier substrate 105 can comprise a single layer or multiple layers, and can include any one or more suitable materials, e.g., sapphire, glass, or silicon. With the carrier substrate 105 in place, the support substrate 400 is removed (e.g., as in FIGS. 3G, 4G, and 5F), after which the polymer layer 402 is removed from the light-emitting devices 15 and the carrier substrate 105 (e.g., as in FIGS. 3H, 4H, and 5G), yielding the generic inventive arrangement of FIGS. 2A and 2B. Any suitable removal process can be employed for removing the substrate 400, e.g., a laser lift-off process, a wet etch process, a hybrid of mechanical thinning plus laser lift-off, or a hybrid of mechanical thinning and wet etching. Any suitable removal process can be employed for removing the polymer layer 402, e.g., one or more plasma removal processes (such as plasma ashing) or one or more wet removal processes (such as a solvent-based removal process). Any process employed for removing the polymer layer 402 should leave intact the attachment of the carrier posts 110 to the carrier substrate 105 and to the attachment areas 18 of the light-emitting devices 15. Removal of the polymer layer 402 leaves the carrier posts 110 as the only attachment between each light-emitting device 15 and the carrier substrate 105, and leaves the light-emitting devices 15 spaced apart from the carrier substrate 105, yielding the inventive structure described above and shown in FIGS. 2A and 2B. Note that FIGS. 3H, 4H, and 5G are inverted relative to FIG. 2B.

In addition to the preceding, the following example embodiments fall within the scope of the present disclosure or appended claims. Any given Example below that refers to multiple preceding Examples shall be understood to refer to only those preceding Examples with which the given Example is not inconsistent, and to exclude implicitly those preceding Examples with which the given Example is inconsistent.

### Example 1

A light-emitting apparatus comprising: (a) a carrier substrate; (b) a multitude of semiconductor light-emitting devices arranged as an array on the carrier substrate, the array of light-emitting devices being characterized by an array spacing and a device separation; (c) for each light-emitting device of the array, a corresponding carrier post between the light-emitting device and the carrier substrate that connects that light-emitting device to the carrier substrate so that the light-emitting device is spaced apart from the carrier substrate, the carrier post (i) forming the only attachment between the light-emitting device and the carrier substrate, (ii) being positioned within an areal extent of the light-emitting device, and (iii) being attached to the light-emitting device at an attachment area thereof that occupies only a fractional portion of the areal extent of the light-emitting device.

### Example 2

The light-emitting apparatus of Example 1, the light-emitting devices being light-emitting diodes (LEDs) that include one or more doped or undoped III-V semiconductor materials or combinations, mixtures, or alloys thereof.

### Example 3

The light-emitting apparatus of any one of Examples 1 or 2, each of the carrier posts including one or more metallic, dielectric, or polymeric materials, and the attachment area of each of the light-emitting devices including one or more metallic or dielectric materials.

### Example 4

The light-emitting apparatus of any one of Examples 1 through 3, the one or more materials of the carrier posts (i) extending across the carrier substrate between the carrier posts and (ii) being spaced apart from the light-emitting devices.

### Example 5

The light-emitting apparatus of any one of Examples 1 through 4, an interface between the attachment area of each light-emitting device and the corresponding carrier post exhibiting tensile strength that is less than tensile strength of the carrier post, less than tensile strength of an attachment of the carrier post to the carrier substrate, and less than tensile strength of the light-emitting device.

### Example 6

The light-emitting apparatus of any one of Examples 1 through 5, an interface between the attachment area of each light-emitting device and the corresponding carrier post being a metal-metal interface, a metal-dielectric interface, a dielectric-dielectric interface, a metal-polymer interface, or a dielectric-polymer interface.

### Example 7

The light-emitting apparatus of any one of Examples 1 through 6, the carrier post including silicon oxide, silicon nitride, or silicon oxynitride.

### Example 8

The light-emitting apparatus of any one of Examples 1 through 7, the attachment area of each light-emitting device includes one or more metallic materials in electrical contact with, or forming at least a portion of, an electrical contact of the light-emitting device.

### Example 9

The light-emitting device of any one of Examples 1 through 7, the attachment area of each light-emitting device including a portion of a dielectric layer that extends across the light-emitting device, the dielectric layer including one or more grooves or perforations that form an interface between the attachment area and a remainder of the dielectric layer, so that tensile strength of the interface is less than tensile strength exhibited by the carrier post, less than tensile strength exhibited by an attachment of the carrier post to the carrier substrate, and less than tensile strength exhibited by the light-emitting device.

### Example 10

The light-emitting device of any one of Examples 1 through 9 wherein (i) the device separation is less than 50 microns, less than 20 microns, less than 10 microns, less than 5 micron, less than 2 micron, or less than 1 micron, and (ii) the device spacing is less than 200 microns, less than 100 microns, less than 50 microns, less than 20 microns, less than 10 microns, less than 5 microns, less than 2 microns, or less than 1 micron.

### Example 11

The light-emitting device of any one of Examples 1 through 10 wherein the array of light-emitting devices includes at least 10⁴ light-emitting devices.

### Example 12

A method for making the optical apparatus of any one of Examples 1 through 11, the method comprising: (A) depositing one or more polymer precursors onto the multitude of semiconductor light-emitting devices arranged as the array on the support substrate, the polymer precursor covering, and filling spaces between, the light-emitting devices of the array; (B) curing the one or more polymer precursors deposited in part (A) to form a solid polymer layer; (C) forming on the attachment area of each one of the light-emitting devices the corresponding carrier post with each carrier post attached at the first end thereof to the attachment area of the corresponding light-emitting device and extending through the polymer layer so that the second end of each of the carrier posts is exposed at the surface of the polymer layer, each of the carrier posts being positioned within the areal extent of the corresponding light-emitting device, the attachment area of each light-emitting device occupying only a fractional portion of the areal extent thereof; (D) forming the carrier substrate on, or attaching the carrier substrate to, the surface of the polymer layer, the carrier substrate being attached to the exposed second ends of the carrier posts, the light-emitting devices being between the support substrate and the carrier substrate; (E) removing the support substrate from the light-emitting devices; and (F) removing the polymer layer from the light-emitting devices and the carrier substrate, leaving (i) the carrier posts as the only attachment between each light-emitting device and the carrier substrate and (ii) the light-emitting devices spaced apart from the carrier substrate.

### Example 13

A method comprising: (A) depositing one or more polymer precursors onto a multitude of semiconductor light-emitting devices arranged as an array on a support substrate, the polymer precursor covering, and filling spaces between, the light-emitting devices of the array, the array of light-emitting devices being characterized by an array spacing and a device separation; (B) curing the one or more polymer precursors deposited in part (A) to form a solid polymer layer; (C) forming on an attachment area of each one of the light-emitting devices a corresponding carrier post with each carrier post attached at a first end thereof to the attachment area of the corresponding light-emitting device and extending through the polymer layer so that a second end of each of the carrier posts is exposed at a surface of the polymer layer, each of the carrier posts being positioned within an areal extent of the corresponding light-emitting device, the attachment area of each light-emitting device occupying only a fractional portion of the areal extent thereof; (D) forming a carrier substrate on, or attaching a carrier substrate to, a surface of the polymer layer, the carrier substrate being attached to the exposed second ends of the carrier posts, the light-emitting devices being between the support substrate and the carrier substrate; (E) removing the support substrate from the light-emitting devices; and (F) removing the polymer layer from the light-emitting devices and the carrier substrate, leaving (i) the carrier posts as the only attachment between each light-emitting device and the carrier substrate and (ii) the light-emitting devices spaced apart from the carrier substrate.

### Example 14

The method of any one of Examples 12 or 13 further comprising: (G) adhering a transfer substrate or transfer tool to the array of light-emitting devices so that the light-emitting devices are between the carrier substrate and the transfer substrate or transfer tool; and (H) separating the transfer substrate or transfer tool from the carrier substrate so that the carrier posts separate from the corresponding light emitting-devices and the array of light-emitting devices remains adhered to the transfer substrate or transfer tool.

### Example 15

The method of Example 14, an interface between the attachment area of each light-emitting device and the corresponding carrier post exhibiting tensile strength that is less than tensile strength of an interface between the transfer substrate and the light-emitting devices, less that tensile strength of the carrier post, less than tensile strength of an attachment of the carrier posts to the carrier substrate, and less than tensile strength of the light-emitting devices.

### Example 16

The method of any one of Examples 14 or 15 further comprising: (I) attaching the array of light-emitting devices to a backplane, interconnect layer, or circuit board so that the light-emitting devices are between the transfer substrate and the backplane, interconnect layer, or circuit board; and (J) separating the transfer substrate or transfer tool from the array of light-emitting devices so that the light-emitting devices remain attached to the backplane, interconnect layer, or circuit board.

### Example 17

The method of any one of Examples 12 through 16 wherein forming the carrier posts in part (C) comprises forming the carrier posts before depositing the one or more polymer precursors in part (A).

### Example 18

The method of any one of Examples 12 through 16 wherein forming the carrier posts in part (C) comprises, after curing the one or more polymer precursors in part (B), (i) etching a corresponding hole through the polymer layer to expose the attachment area of each light-emitting device of the array, and (ii) forming the corresponding carrier post in each of the holes.

### Example 19

The method of Example 18 wherein forming the corresponding carrier post in each of the holes comprises growing or depositing one or more carrier post materials to fill the holes and to form a layer on the polymer layer that extends between the carrier posts and is spaced apart from the light-emitting devices.

### Example 20

The method of any one of Examples 12 through 19 wherein forming the carrier posts in part (C) includes planarizing the polymer layer and the second ends of the carrier posts.

### Example 21

The method of any one of Examples 12 through 20 wherein removing the polymer layer in part (E) includes one or more plasma removal processes or one or more wet removal processes.

### Example 22

The method of Example 21, each of the carrier posts including one or more metallic, dielectric, or polymeric materials that are resistant to the one or more plasma removal processes or resistant to the one or more wet removal processes.

### Example 23

The method of any one of Examples 12 through 22 wherein (i) the device separation is less than 50 microns, less than 20 microns, less than 10 microns, less than 5 micron, less than 2 micron, or less than 1 micron, (ii) the device spacing is less than 200 microns, less than 100 microns, less than 50 microns, less than 20 microns, less than 10 microns, less than 5 microns, less than 2 microns, or less than 1 micron, or (iii) the array of light-emitting device includes at least 10⁴ light-emitting devices.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features—which features are shown, described, or claimed in the present application—including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open-ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth, or if a differing interpretation is implicit or inherent (e.g., some small integer quantities). For null quantities described by phrases such as “equal to zero,” “absent,” “eliminated,” “negligible,” “prevented,” and so forth (with or without terms such as “about,” “substantially,” and so forth), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled. Terms such as “parallel,” “perpendicular,” “orthogonal,” “flush,” “aligned,” and so forth shall be similarly interpreted (with or without terms such as “about,” “substantially,” and so forth).

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light-emitting apparatus comprising:
(a) a carrier substrate;
(b) a multitude of semiconductor light-emitting devices arranged as an array on the carrier substrate, the array of light-emitting devices being characterized by an array spacing and a device separation;
(c) for each light-emitting device of the array, a corresponding carrier post between the light-emitting device and the carrier substrate that connects that light-emitting device to the carrier substrate so that the light-emitting device is spaced apart from the carrier substrate, the carrier post (i) forming the only attachment between the light-emitting device and the carrier substrate, (ii) being positioned within an areal extent of the light-emitting device, and (iii) being attached to the light-emitting device at an attachment area thereof that occupies only a fractional portion of the areal extent of the light-emitting device.

2. The light-emitting apparatus of claim 1, the light-emitting devices being light-emitting diodes (LEDs) that include one or more doped or undoped III-V semiconductor materials or combinations, mixtures, or alloys thereof.

3. The light-emitting apparatus of claim 1, each of the carrier posts including one or more metallic, dielectric, or polymeric materials, and the attachment area of each of the light-emitting devices including one or more metallic or dielectric materials.

4. The light-emitting apparatus of claim 3, the one or more materials of the carrier posts (i) extending as a layer on the carrier substrate between the carrier posts and (ii) being spaced apart from the light-emitting devices.

5. The light-emitting apparatus of claim 3, an interface between the attachment area of each light-emitting device and the corresponding carrier post exhibiting tensile strength that is less than tensile strength of the carrier post, less than tensile strength of an attachment of the carrier post to the carrier substrate, and less than tensile strength of the light-emitting device.

6. The light-emitting apparatus of claim 3, an interface between the attachment area of each light-emitting device and the corresponding carrier post being a metal-metal interface, a metal-dielectric interface, a dielectric-dielectric interface, a metal-polymer interface, or a dielectric-polymer interface.

7. The light-emitting apparatus of claim 3, the carrier post including silicon oxide, silicon nitride, or silicon oxynitride.

8. The light-emitting apparatus of claim 3, the attachment area of each light-emitting device includes one or more metallic materials in electrical contact with, or forming at least a portion of, an electrical contact of the light-emitting device.

9. The light-emitting device of claim 3, the attachment area of each light-emitting device including a portion of a dielectric layer that extends across the light-emitting device, the dielectric layer including one or more grooves or perforations that form an interface between the attachment area and a remainder of the dielectric layer, so that tensile strength of the interface is less than tensile strength exhibited by the carrier post, less than tensile strength exhibited by an attachment of the carrier post to the carrier substrate, and less than tensile strength exhibited by the light-emitting device.

10. The light-emitting device of claim 1 wherein (i) the device separation is less than 50 microns, and (ii) the device spacing is less than 200 microns.

11. The light-emitting device of claim 1 wherein the array of light-emitting devices includes at least 10⁴ light-emitting devices.

12. A method comprising:
(A) depositing one or more polymer precursors onto a multitude of semiconductor light-emitting devices arranged as an array on a support substrate, the polymer precursor covering, and filling spaces between, the light-emitting devices of the array, the array of light-emitting devices being characterized by an array spacing and a device separation;
(B) curing the one or more polymer precursors deposited in part (A) to form a solid polymer layer;
(C) forming on an attachment area of each one of the light-emitting devices a corresponding carrier post with each carrier post attached at a first end thereof to the attachment area of the corresponding light-emitting device and extending through the polymer layer so that a second end of each of the carrier posts is exposed at a surface of the polymer layer, each of the carrier posts being positioned within an areal extent of the corresponding light-emitting device, the attachment area of each light-emitting device occupying only a fractional portion of the areal extent thereof;
(D) forming a carrier substrate on, or attaching a carrier substrate to, a surface of the polymer layer, the carrier substrate being attached to the exposed second ends of the carrier posts, the light-emitting devices being between the support substrate and the carrier substrate;
(E) removing the support substrate from the light-emitting devices; and
(F) removing the polymer layer from the light-emitting devices and the carrier substrate, leaving (i) the carrier posts as the only attachment between each light-emitting device and the carrier substrate and (ii) the light-emitting devices spaced apart from the carrier substrate.

13. The method of claim 12 further comprising:
(G) adhering a transfer substrate or transfer tool to the array of light-emitting devices so that the light-emitting devices are between the carrier substrate and the transfer substrate or transfer tool; and
(H) separating the transfer substrate or transfer tool from the carrier substrate so that the carrier posts separate from the corresponding light emitting-devices and the array of light-emitting devices remains adhered to the transfer substrate or transfer tool.

14. The method of claim 13, an interface between the attachment area of each light-emitting device and the corresponding carrier post exhibiting tensile strength that is less than tensile strength of an interface between the transfer substrate and the light-emitting devices, less that tensile strength of the carrier post, less than tensile strength of an attachment of the carrier posts to the carrier substrate, and less than tensile strength of the light-emitting devices.

15. The method of claim 13 further comprising:
(I) attaching the array of light-emitting devices to a backplane, interconnect layer, or circuit board so that the light-emitting devices are between the transfer substrate and the backplane, interconnect layer, or circuit board; and
(J) separating the transfer substrate or transfer tool from the array of light-emitting devices so that the light-emitting devices remain attached to the backplane, interconnect layer, or circuit board.

16. The method of claim 12 wherein forming the carrier posts in part (C) comprises, after curing the one or more polymer precursors in part (B), (i) etching a corresponding hole through the polymer layer to expose the attachment area of each light-emitting device of the array, and (ii) forming the corresponding carrier post in each of the holes.

17. The method of claim 16 wherein forming the corresponding carrier post in each of the holes comprises growing or depositing one or more carrier post materials to fill the holes and to form a layer on the polymer layer between the carrier posts.

18. The method of claim 12 wherein removing the polymer layer in part (E) includes one or more plasma removal processes or one or more wet removal processes.

19. The method of claim 18, each of the carrier posts including one or more metallic, dielectric, or polymeric materials that are resistant to the one or more plasma removal processes or resistant to the one or more wet removal processes.

20. The method of claim 12 wherein (i) the device separation is less than 50 microns, (ii) the device spacing is less than 200 microns, or (iii) the array of light-emitting device includes at least 10⁴ light-emitting devices.
